(19) United States
(12) Patent Application Publication
(10) Pub. No.: US 2026/0165217 A1
(43) Pub. Date: Jun. 11, 2026

(54) SEMICONDUCTOR MEMORY MODULE

(71) Applicant: Samsung Electronics Co., Ltd., Suwon-si (KR)

(72) Inventors: KI-HONG JEONG, Suwon-si (KR); HONGJIN KIM, Suwon-si (KR)

(73) Assignee: Samsung Electronics Co., Ltd., Suwon-si (KR)

(21) Appl. No.: 19/258,027

(22) Filed: Jul. 2, 2025

(30) Foreign Application Priority Data
Dec. 9, 2024 (KR) 10-2024-0181860

(51) Int. Cl. H10W 90/00; H10B 80/00; H10W 70/60; H10W 90/24

(52) U.S. Cl. CPC H10W 90/401; H10W 70/611; H10W 90/24; H10B 80/00; H10W 90/752; H10W 90/754

(57) ABSTRACT

Provided is a semiconductor memory module including a module substrate including a first surface and a second surface that are opposite to each other, a first semiconductor package and a second semiconductor package on the first surface of the module substrate and side by side in a first direction, a third semiconductor package on the second surface of the module substrate and partially overlapping the first semiconductor package and the second semiconductor package in a second direction perpendicular to the first direction, first passive elements on the first surface of the module substrate and between the first semiconductor package and the second semiconductor package, and second passive elements on the second surface of the module substrate and on a side of the third semiconductor package in the first direction, wherein at least one of the first passive elements overlaps the third semiconductor package in the second direction.

### CROSS-REFERENCE TO RELATED APPLICATIONS

This application claims priority to Korean Patent Application No. 10-2024-0181860 filed on Dec. 9, 2024, in the Korean Intellectual Property Office, the disclosure of which is incorporated herein in its entirety by reference.

### BACKGROUND

Embodiments of the present disclosure relate to a semiconductor memory module.

Many electronic systems include semiconductor memory modules, such as solid state drives (SSDs), dual in-line memory modules (DIMMs), and small outline-DIMMs, all of which utilize memory cells to store data as an electrical charge or voltage. Improvements in storage density of these modules have been brought about by increasing the density of the memory cells on each individual memory component using enhanced manufacturing techniques. Additionally, the storage density of these modules has also been increased by including more memory components in each memory device or module using advanced board-level packaging techniques.

### SUMMARY

One or more embodiments provide a semiconductor memory module with improved electrical characteristics.

According to an aspect of one or more embodiments, there is provided a semiconductor memory module including a module substrate including a first surface and a second surface that are opposite to each other, a first semiconductor package and a second semiconductor package on the first surface of the module substrate and side by side in a first direction, a third semiconductor package on the second surface of the module substrate and partially overlapping the first semiconductor package and the second semiconductor package in a second direction perpendicular to the first direction, first passive elements on the first surface of the module substrate and between the first semiconductor package and the second semiconductor package, and second passive elements on the second surface of the module substrate and on a side of the third semiconductor package in the first direction, wherein at least one of the first passive elements overlaps the third semiconductor package in the second direction.

According to another aspect of one or more embodiments, there is provided a semiconductor memory module including a module substrate including a first surface and a second surface that are opposite to each other, a first semiconductor package and a second semiconductor package on the first surface of the module substrate and side by side in a first direction, first connection members between the first second semiconductor package and the module substrate and between the second semiconductor package and the module substrate, a third semiconductor package on the second surface of the module substrate and partially overlapping the first semiconductor package and the second semiconductor package in a second direction perpendicular to the first direction, second connection members between the third semiconductor package and the module substrate, first passive elements on the first surface of the module substrate and between the first semiconductor package and the second semiconductor package, and second passive elements on the second surface of the module substrate and the third semiconductor package, wherein the first connection members include first signal connection members overlapping a peripheral portion of the first semiconductor package and a peripheral portion the second semiconductor package in the second direction, and first sub-connection members overlapping a central portion of the first semiconductor package and a central portion of the second semiconductor package in the second direction, wherein the second connection members include second signal connection members overlapping, in the second direction, a peripheral portion of the third semiconductor package, and second sub-connection members overlapping, in the second direction, a central portion of the third semiconductor package, and wherein some of the first signal connection members are connected to and overlap second signal connection members, respectively, in the second direction.

According to still another aspect of one or more embodiments, there is provided a semiconductor memory module including a module substrate including a first surface and a second surface that are opposite to each other, a first semiconductor package and a second semiconductor package on the first surface of the module substrate and side by side in a first direction, a third semiconductor package on the second surface of the module substrate and partially overlapping the first semiconductor package and the second semiconductor package in a second direction perpendicular to the first direction, a fourth semiconductor package on the second surface of the module substrate and partially overlapping the second semiconductor package in the second direction, first passive elements on the first surface of the module substrate and between the first semiconductor package and the second semiconductor package, and adjacent to a periphery of the first semiconductor package and a periphery of the second semiconductor package, and second passive elements on the second surface and between the third semiconductor package and the fourth semiconductor package, and adjacent to a periphery of the third semiconductor package and a periphery of the fourth semiconductor package, wherein a distance between the first semiconductor package and the second semiconductor package in the first direction is equal to a distance between the third semiconductor package and the fourth semiconductor package in the first direction.

According to further still another aspect of one or more embodiments, there is provided a method of manufacturing a semiconductor memory module including forming a module substrate having a first surface and a second surface that are opposite to each other, forming a first semiconductor package and a second semiconductor package on the first surface of the module substrate and side by side in a first direction, forming a third semiconductor package on the second surface of the module substrate and partially overlapping the first semiconductor package and the second semiconductor package in a second direction perpendicular to the first direction, forming first passive elements on the first surface of the module substrate and between the first semiconductor package and the second semiconductor package, and forming second passive elements on the second surface of the module substrate and adjacent to the third semiconductor package, wherein at least one of the first passive elements is formed to overlap the third semiconductor package in the second direction.

The method may further include forming a fourth semiconductor package on the second surface of the module substrate and partially overlapping the second semiconductor package in the second direction.

The method may further include forming first signal connection members between peripheral portions of the first and second semiconductor packages and the module substrate, forming first sub-connection members between central portions of the first and second semiconductor packages and the module substrate, forming second signal connection members between a peripheral portion of the third semiconductor package and the module substrate, and forming second sub-connection members between a central portion of the third semiconductor package and the module substrate.

The method may further include forming a third passive element on the first surface of the module substrate and spaced apart from the first passive elements in the first direction, the first semiconductor package being between the third passive element and the first passive elements.

The method may further include forming a power circuit chip on the first surface of the module substrate and spaced apart from the first to third semiconductor packages in the first direction.

### BRIEF DESCRIPTION OF DRAWINGS

Embodiments will be more clearly understood from the following detailed description taken in conjunction with the accompanying drawings in which:

FIG. 1 is a block diagram illustrating a schematic configuration of a storage system according to one or more embodiments;

FIG. 2 is a plan view of a semiconductor memory module according to one or more embodiments;

FIG. 3 is a cross-sectional view taken along line A-A′ of FIG. 2 according to one or more embodiments;

FIGS. 4A, 4B, and 4C are cross-sectional views illustrating a process of manufacturing a semiconductor memory module having the cross-section of FIG. 2;

FIG. 5 is a cross-sectional view taken along line A-A′ of FIG. 2 according to one or more embodiments;

FIG. 6 is a cross-sectional view taken along line A-A′ of FIG. 2 according to one or more embodiments;

FIGS. 7A and 7B are cross-sectional views of semiconductor packages according to one or more embodiments;

FIG. 8 is a plan view of a semiconductor memory module according to one or more embodiments; and

FIG. 9 is a cross-sectional view of a semiconductor memory module according to one or more embodiments.

### DETAILED DESCRIPTION

Hereinafter, embodiments will be described with reference to the attached drawings. Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

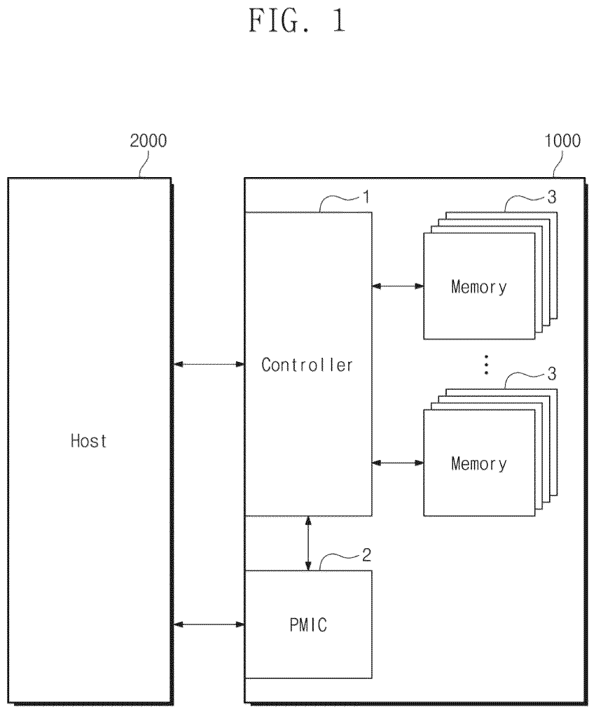

FIG. 1 is a block diagram illustrating a schematic configuration of a storage system according to one or more embodiments.

Referring to FIG. 1, a storage system may include a host 2000 and a semiconductor memory module 1000. The semiconductor memory module 1000 may store or output data in response to a read/write request from the host 2000 (i.e., an external electronic device). For example, the semiconductor memory module 1000 may be a solid state drive (SSD), a dual in-line memory module (DIMM), or a relatively small outline dual in-line memory module (SDO-DIMM).

The semiconductor memory module 1000 may include a controller 1, an input/output interface, a power management integrated circuit (PMIC) chip 2, and a plurality of memory packages 3. The memory packages 3 may be used as a storage medium of the semiconductor memory module 1000. In one or more embodiments, each of the memory packages 3 may include a plurality of nonvolatile memory chips.

For example, the memory packages 3 may be NAND flash memory or vertical NAND (VNAND, or 3D NAND) flash memory chips having a large capacity and high-speed storage capability. As another example, the memory packages 3 may be phase change random access memory (PRAM), magnetic random access memory (MRAM), resistive random access memory (ReRAM), ferromagnetic random access memory (FRAM), dynamic random-access memory (DRAM), or NOR flash memory.

The controller 1 may include a program configured to transmit and receive signals with an external device in a manner according to a serial advanced technology attachment (SATA) standard, a parallel advanced technology attachment (PATA) standard, or a small computer system interface (SCSI) standard.

The PMIC chip 2 may receive power from the host 2000 and supply power to the controller 1. The PMIC chip 2 may be disposed in the semiconductor memory module 1000 as shown in FIG. 1, or may be disposed outside the semiconductor memory module 1000. For example, the PMIC chip 2 may be disposed on a main board and may provide power to the semiconductor memory module 1000.

In one or more embodiments, the controller 1, the PMIC chip 2, and the plurality of memory packages 3 may be disposed on the same printed circuit board (PCB). In this case, the controller 1, the PMIC chip 2, and the plurality of memory packages 3 may be connected to each other through wiring lines formed on the printed circuit board.

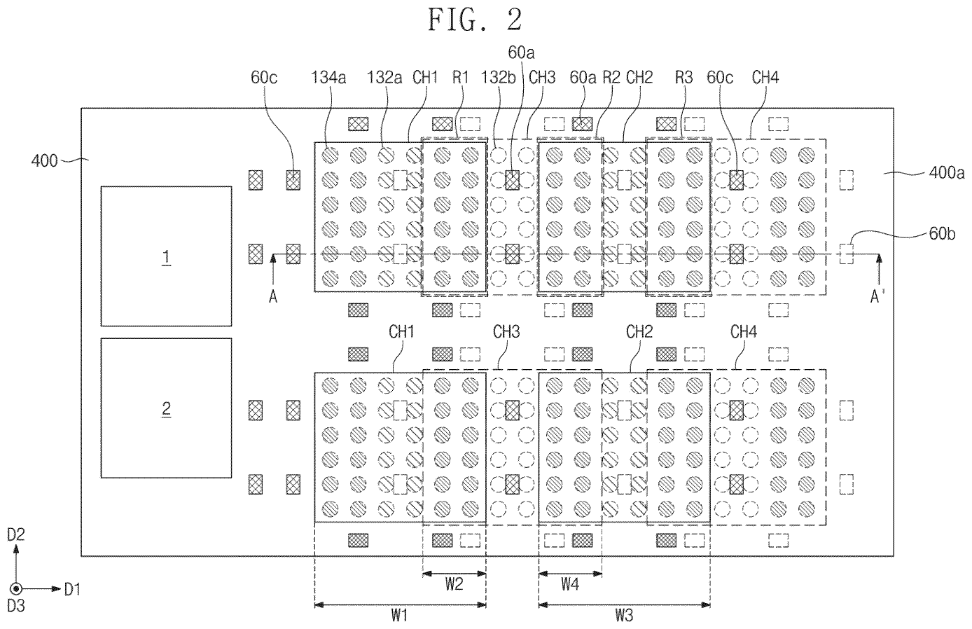

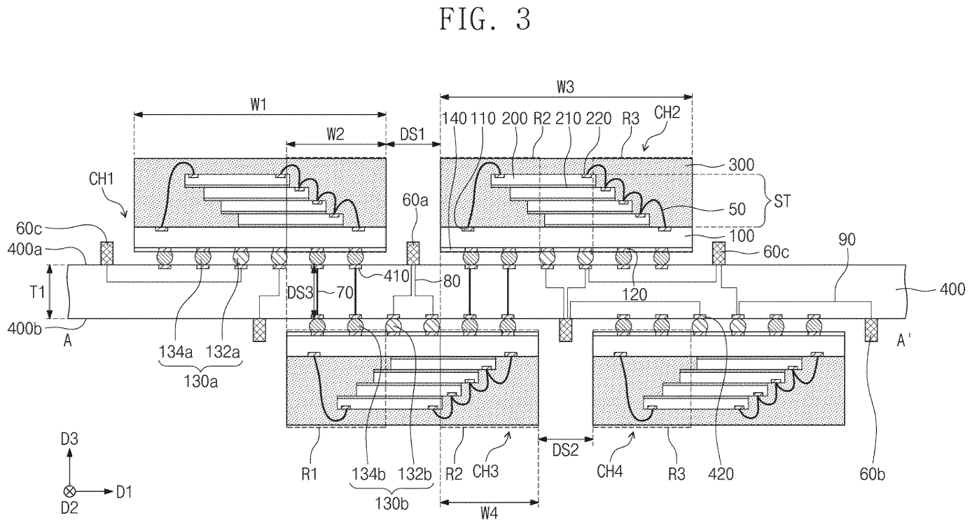

FIG. 2 is a plan view of a semiconductor memory module according to one or more embodiments. FIG. 3 is a cross-sectional view taken along line A-A′ of FIG. 2 according to one or more embodiments.

Referring to FIGS. 2 and 3, a semiconductor memory module according to one or more embodiments may include a module substrate 400. The module substrate 400 may include a first surface 400a and a second surface 400b that are opposite to each other. The module substrate 400 may be, for example, a double-sided or multi-layer printed circuit board.

A first semiconductor package CH1, a second semiconductor package CH2, a third semiconductor package CH3, and a fourth semiconductor package CH4 may be mounted on the module substrate 400. At least some of the first to fourth semiconductor packages CH1, CH2, CH3, and CH4 may independently be memory device chips, such as NAND flash memory chips, DRAM chips, SRAM chips, EEPROM chips, PRAM chips, MRAM chips, ReRAM chips, high bandwidth memory (HBM) chips, hybrid memory cubic (HMC) chips, and the like. As another example, at least some of the first to fourth semiconductor packages CH1, CH2, CH3, and CH4 may independently be system large scale integration (LSI) chips, logic circuit chips. As another example, another some of the first to fourth semiconductor packages CH1, CH2, CH3, and CH4 may independently be microelectromechanical system (MEMS) device chips, or application-specific integrated circuit (ASIC) chips.

The first semiconductor package CH1 and the second semiconductor package CH2 may be mounted on the first surface 400a of the module substrate 400. The first semiconductor package CH1 and the second semiconductor package CH2 may be disposed side by side in a first direction D1, parallel to the first surface 400a of the module substrate 400, and may be spaced apart from each other. The first direction D1 may be parallel to the first surface 400a of the module substrate 400.

The third semiconductor package CH3 and the fourth semiconductor package CH4 may be mounted on the second surface 400b of the module substrate 400. The third semiconductor package CH3 and the fourth semiconductor package CH4 may be disposed side by side in the first direction D1 and may be spaced apart from each other. The third semiconductor package CH3 may partially overlap the first semiconductor package CH1 and the second semiconductor package CH2, respectively, in a third direction D3 perpendicular to the first direction and the first surface 400a of the module substrate 400. The fourth semiconductor package CH4 may partially overlap the second semiconductor package CH2 in the third direction D3.

A plurality of first semiconductor packages CH1, a plurality of second semiconductor packages CH2, a plurality of third semiconductor packages CH3, and a plurality of fourth semiconductor packages CH4 may be provided. For example, as illustrated in FIG. 2, each of the first to fourth semiconductor packages CH1, CH2, CH3, and CH4 may be provided in two. However, embodiments are not limited thereto, and each of the first to fourth semiconductor packages CH1, CH2, CH3, and CH4 may be provided one.

First passive elements 60a may be mounted on the first surface 400a of a module substrate 400 and may be disposed between the first semiconductor package CH1 and the second semiconductor package CH2. At least one of the first passive elements 60a may vertically overlap the third semiconductor package CH3 in the third direction D3. Second passive elements 60b may be mounted on the second surface 400b of the module substrate 400 and may be disposed around and adjacent to a periphery of the third semiconductor package CH3 and a periphery of the fourth semiconductor package CH4. Some of the second passive elements 60b may be disposed between the third semiconductor package CH3 and the fourth semiconductor package CH4. At least one of the second passive elements 60b may vertically overlap the second semiconductor package CH2 in the third direction D3. When viewed in a plan view, the first passive elements 60a may be spaced apart from the second passive elements 60b in the first direction D1 or a second direction D2 perpendicular to the first direction D1. The second direction D2 may be parallel to the first surface 400a of the module substrate 400.

Third passive elements 60c may be mounted on the first surface 400a of the module substrate 400 and may be spaced apart from the first passive elements 60a with the first semiconductor package CH1 interposed between the third passive elements 60c and the first passive elements 60a. The third passive elements 60c may be spaced apart from the first passive elements 60a with the second semiconductor package CH2 interposed between the third passive elements 60c and the first passive elements 60a. At least one of the third passive elements 60c may vertically overlap the fourth semiconductor package CH4 in the third direction D3. When viewed in a plan view, the first passive elements 60a and the third passive elements 60c may surround the first semiconductor package CH1 and the second semiconductor package CH2, respectively. Each of the first to third passive elements 60a, 60b, and 60c may independently be, for example, a resistor, a capacitor, an inductor, a thermistor, an oscillator, a ferrite bead, an antenna, a varistor, or a crystal.

First conductive pads 410 may be disposed on the first surface 400a of the module substrate 400. The first conductive pads 410 may be spaced apart from the first and third passive elements 60a and 60c. Second conductive pads 420 may be disposed on the second surface 400b of the module substrate 400. The second conductive pads 420 may be spaced apart from the second passive elements 60b. The first and second conductive pads 410 and 420 may each include at least one metal, for example, copper (Cu), gold (Au), nickel (Ni), tin (Sn), silver (Ag), tungsten (W), and aluminum (Al).

The first semiconductor package CH1 may have a first width W1 in the first direction D1. The third semiconductor package CH3 may have a first portion R1 overlapping the first semiconductor package CH1. The first portion R1 may have a second width W2 in the first direction D1, and the second width W2 may be 0.3 to 0.5 times the first width W1.

The second semiconductor package CH2 may have a third width W3 in the first direction D1. The third semiconductor package CH3 may have a second portion R2 overlapping the second semiconductor package CH2. The second semiconductor package CH2 may have a third portion R3 overlapping the fourth semiconductor package CH4. The second portion R2 may have a fourth width W4 in the first direction D1. The fourth width W4 may be 0.3 to 0.5 times the third width W3. For example, the first width W1 of the first semiconductor package CH1 may be the same as the third width W3 of the second semiconductor package CH2. For example, the first to fourth semiconductor packages CH1, CH2, CH3, and CH4 may have the same first width W1 in the first direction D1, but are not limited thereto.

In the first direction D1, a first distance DS1 between the first semiconductor package CH1 and the second semiconductor package CH2 may be the same as a second distance DS2 between the third semiconductor package CH3 and the fourth semiconductor package CH4.

Each of the first to fourth semiconductor packages CH1, CH2, CH3, and CH4 may include a first substrate 100, a stacked structure ST, bonding wires 50, and a first molding member 300. The first substrate 100 may include, for example, a printed circuit board, a flexible substrate, a tape substrate, etc. The first substrate 100 may be a multilayer circuit board having vias and various circuits therein.

Third conductive pads 110 may be disposed on an upper surface of the first substrate 100. Fourth conductive pads 120 may be disposed on a lower surface of the first substrate 100 opposite to the third conductive pads 110. The third conductive pads 110 and the fourth conductive pads 120 may each include, for example, at least one metal among copper (Cu), gold (Au), nickel (Ni), tin (Sn), silver (Ag), tungsten (W), and aluminum (Al). A protective layer 140 may be disposed on and cover the lower surface of the first substrate 100 and the fourth conductive pads 120. The protective layer 140 may include at least one among silicon oxide, silicon nitride, and silicon carbon nitride.

The stacked structure ST may be disposed on the first substrate 100. The stacked structure ST may include a plurality of semiconductor dies 200 sequentially stacked on the first substrate 100. Although four chips are illustrated in FIG. 3, the number of chips included in the stacked structure ST may be variously changed, such as, for example, 8, 16, or 24. The semiconductor dies 200 may include a nonvolatile memory device, such as a NAND flash memory. Each of the semiconductor dies 200 may include the same type of semiconductor die.

An adhesive member 210 may be interposed between the semiconductor die 200 and the first substrate 100 and between the semiconductor dies 200. The adhesive member 210 may include, for example, a die attach film (DAF) or an epoxy resin.

Chip pads 220 may be disposed on an upper surface of each of the semiconductor dies 200. The chip pads 220 may include at least one metal among, for example, copper (Cu), gold (Au), nickel (Ni), tin (Sn), silver (Ag), tungsten (W), and aluminum (Al).

The semiconductor dies 200 may be connected to the first substrate 100 in a wire bonding manner. For example, the bonding wires 50 may connect the chip pads 220 to the third conductive pads 110 of the corresponding first substrate 100, respectively. The bonding wires 50 may include a conductive material.

The first molding member 300 may be disposed on and cover the first substrate 100, the stacked structure ST, and the bonding wires 50. The first molding member 300 may include an insulating resin, such as, for example, an epoxy-based molding compound (EMC). The first molding member 300 may further include a filler, and the filler may be dispersed in the insulating resin.

First connection members 130a may be bonded to the fourth conductive pads 120 of the first and second semiconductor packages CH1 and CH2, respectively. The first connection members 130a may be interposed between the first and second semiconductor packages CH1 and CH2 and the module substrate 400, and may connect the first and second semiconductor packages CH1 and CH2 and the module substrate 400. Second connection members 130b may be bonded to the fourth conductive pads 120 of the third and fourth semiconductor packages CH3 and CH4, respectively. The second connection members 130b may be interposed between the third and fourth semiconductor packages CH3 and CH4 and the module substrate 400 and may connect the third and fourth semiconductor packages CH3 and CH4 and the module substrate 400. The first and second connection members 130a and 130b may include, for example, at least one of a copper bump, a copper pillar, and a solder ball.

Each of the first connection members 130a may include first sub-connection members 132a and first signal connection members 134a. The first sub-connection members 132a may be interposed between a central portion of each the first and second semiconductor packages CH1 and CH2 and the module substrate 400. For example, the first sub-connection members 132a may be between a central portion of the first semiconductor package CH1 in the first direction D1 and the module substrate 400, and may be between a central portion of the second semiconductor package CH2 in the first direction D1 and the module substrate 400. The first signal connection members 134a may be interposed between a peripheral portion of each of the first and second semiconductor packages CH1 and CH2 and the module substrate 400. For example, the first signal connection members 134a may be between a peripheral portion of the first semiconductor package CH1 in the first direction D1 and the module substrate 400, and may be between a peripheral portion of the second semiconductor package CH2 in the first direction D1 and the module substrate 400.

Each of the second connection members 130b may include second sub-connection members 132b and second signal connection members 134b. The second sub-connection members 132b may be interposed between central portions of each of the third and fourth semiconductor packages CH3 and CH4 and the module substrate 400. The second signal connection members 134b may be interposed between the peripheral portions of each of the third and fourth semiconductor packages CH3 and CH4 and the module substrate 400.

Some of the first signal connection members 134a may be connected to second signal connection members 134b, respectively, and may overlap each other in the third direction D3. For example, as illustrated in FIG. 3, some of the first signal connection members 134a and the second signal connection members 134b may overlap with each other in the third direction D3 and may be connected to each other. A first wiring line 70 may connect a corresponding one of the first signal connection members 134a to a corresponding one of the second signal connection members 134b. The first and second signal connection members 134a and 134b may be disposed to overlap each other in the first to third portions R1, R2, and R3 in the third direction D3.

A corresponding one of the first signal connection members 134a and a corresponding one of the second signal connection members 134b may overlap each other in the third direction D3, and an electrical signal distance between the first semiconductor package CH1 and the third semiconductor package CH3 and between the second semiconductor package CH2 and the fourth semiconductor package CH4 may be reduced, and thus electrical flow may be made smooth.

The module substrate 400 may have the first thickness T1 in the third direction D3. In the third direction D3, a third distance DS3 between one of the first signal connection members 134a and one of the second signal connection members 134b that overlap each other may be 0.8 to 1.1 times the first thickness T1. The third distance DS3 may be equal to or similar to the first thickness T1 of the module substrate 400, and thus an electrical signal distance between the first semiconductor package CH1 and the third semiconductor package CH3 and between the second semiconductor package CH2 and the fourth semiconductor package CH4 may be reduced. As a result, signal transmission speed may be improved, and inductance and resistance may be reduced. Accordingly, electrical characteristics of the semiconductor memory module may be improved.

Some of the first sub-connection members 132a may be connected to at least one of the second passive elements 60b. A second wiring line 80 may connect a corresponding one of the first sub-connection members 132a and a corresponding one of the second passive elements 60b. Some of the first sub-connection members 132a may be connected to at least one of the third passive elements 60c. A third wiring line 90 may connect a corresponding one of the first sub-connection members 132a to a corresponding one of the third passive elements 60c.

An electrical signal distance between one of the first sub-connection members 132a and the third passive element 60c may be greater than an electrical signal distance between the other one of the first sub-connection members 132a and one of the second passive elements 60b.

Some of the second sub-connection members 132b may be connected to at least one of the first passive elements 60a. The second wiring line 80 may connect a corresponding one of the second sub-connection members 132b to a corresponding one of the first passive elements 60a. Some of the second sub-connection members 132b may be connected to at least one of the second passive elements 60b. The third wiring line 90 may connect a corresponding one of the second sub-connection members 132b and a corresponding one of the second passive elements 60b.

The first to third wiring lines 70, 80, and 90 may have a single-layer or multi-layer structure of at least one of, for example, copper, aluminum, tungsten, titanium, titanium nitride, tantalum, tantalum nitride, ruthenium, and iridium, for example.

The controller 1 and the PMIC chip 2 may be mounted on the first surface 400a of the module substrate 400. When viewed in a plan view, the controller 1 and the PMIC chip 2 may be disposed to be spaced apart from the first to fourth semiconductor packages CH1, CH2, CH3, and CH4 in the first direction D1.

The module substrate 400 and the first to fourth semiconductor packages CH1, CH2, CH3, and CH4 may be electrically connected through the first to third passive elements 60a, 60b, and 60c, and thus power transmitted from the PMIC chip 2 may be more effectively transmitted to the first to fourth semiconductor packages CH1, CH2, CH3, and CH4 disposed far from the PMIC chip 2. As a result, a semiconductor memory module with improved electrical characteristics may be provided.

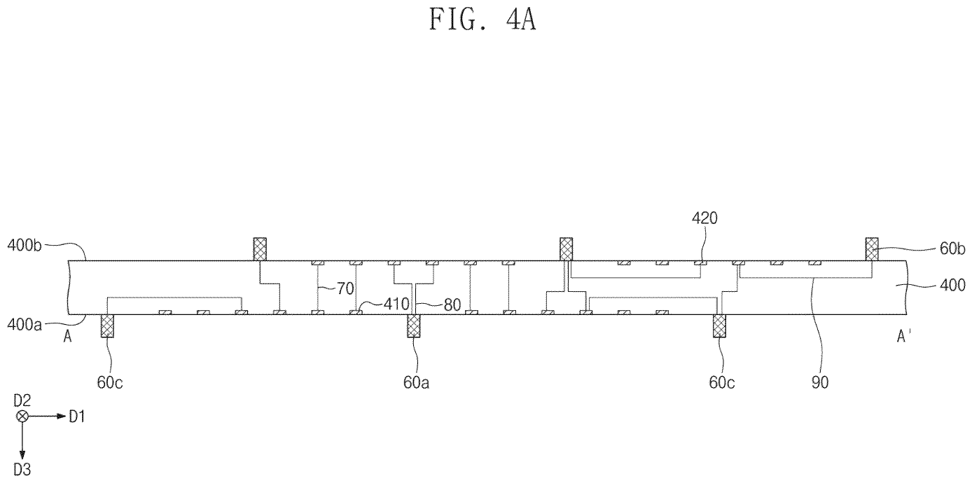

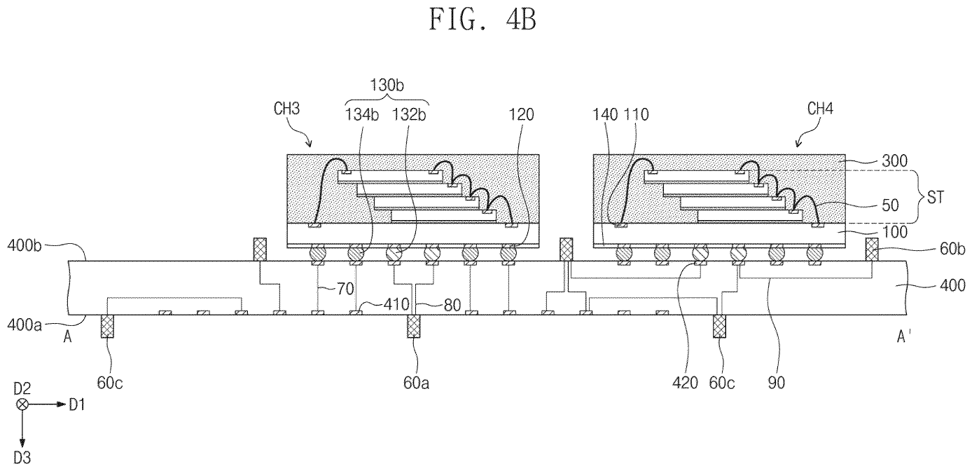

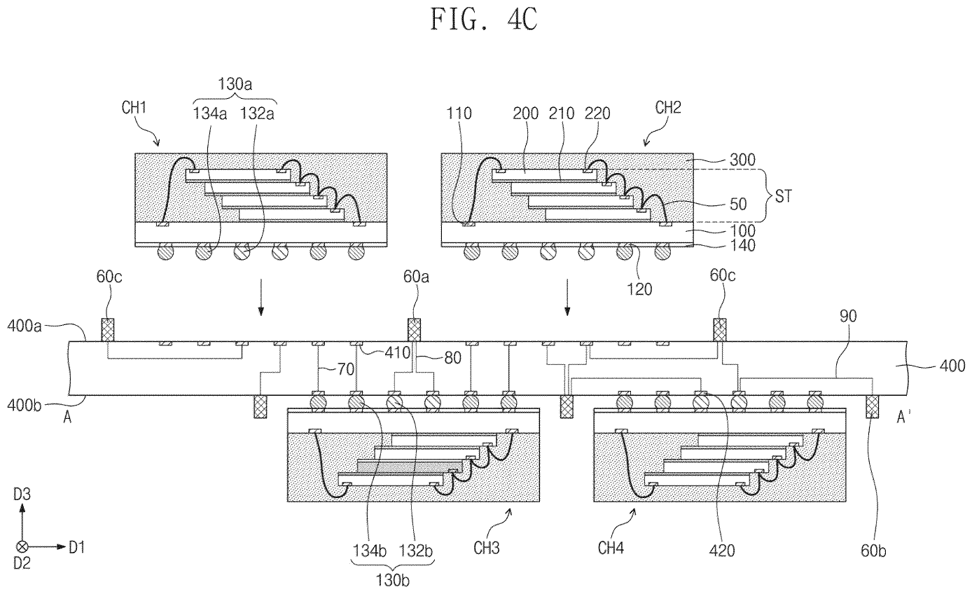

FIGS. 4A to 4C are cross-sectional views illustrating a process of manufacturing a semiconductor memory module having the cross-section of FIG. 2.

Referring to FIG. 4A, a module substrate 400 is prepared in which first conductive pads 410 and first and third passive elements 60a and 60c are formed on a first surface 400a, and second conductive pads 420 and second passive elements 60b are formed on a second surface 400b.

Referring to FIG. 4B, the third and fourth semiconductor packages CH3 and CH4 may be mounted on the second surface 400b of the module substrate 400 by interposing second connection members 130b therebetween. For example, the second connection members 130b may be between the third and fourth semiconductor packages CH3 and CH4 and the second surface 400b of the module substrate 400. The second connection members 130b may be bonded to the second conductive pads 420 through a reflow process.

Referring to FIGS. 2, 3, and 4C, the structure of FIG. 4B may be reversed, and the first and second semiconductor packages CH1 and CH2 may be mounted on the first surface 400a of the module substrate 400 by interposing the first connection members 130a therebetween. For example, the first connection members 130a may be between the first and second semiconductor packages CH1 and CH2 and the first surface 400a of the module substrate 400. In this case, as in FIGS. 2 and 3, the first semiconductor package CH1, the second semiconductor package CH2, and the third semiconductor package CH3 may be disposed to be partially overlapped, and the second semiconductor package CH2 and the fourth semiconductor package CH4 may be disposed to be partially overlapped. The first connection members 130a may be bonded to the first conductive pads 410 by a reflow process.

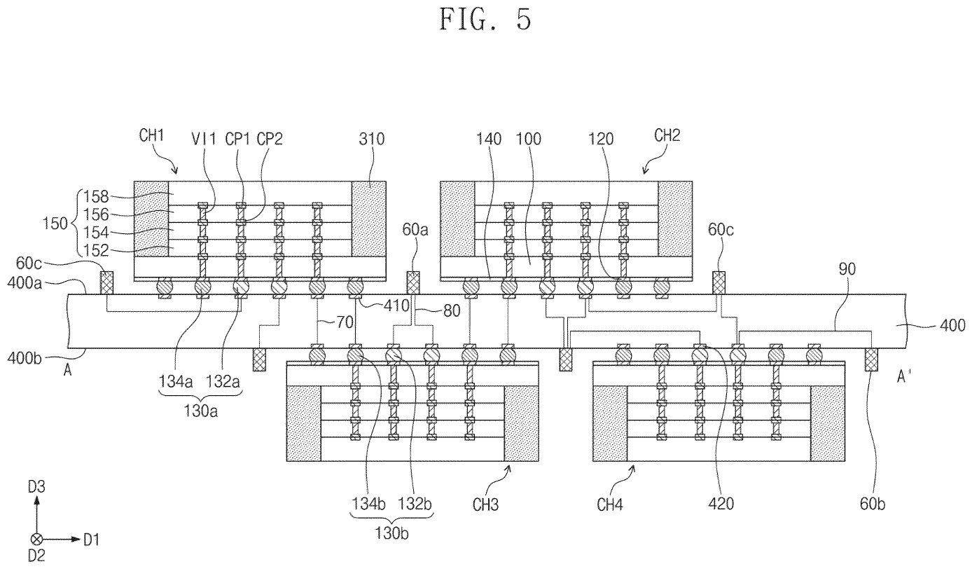

FIG. 5 is a cross-sectional view taken along line A-A′ of FIG. 2 according to one or more embodiments.

Referring to FIG. 5, each of first to fourth semiconductor packages CH1, CH2, CH3, and CH4 according to one or more embodiments may have an high bandwidth memory (HBM) chip structure. Each of the first to fourth semiconductor packages CH1, CH2, CH3, and CH4 may include a memory stacked structure 150 disposed on a first substrate 100. The memory stacked structure 150 may include first to fourth memory chips 152, 154, 156, and 158. The first to fourth memory chips 152, 154, 156, and 158 may include first chip pads CP1 and second chip pads CP2. The first to third memory chips 152, 154, and 156 may include penetration vias VI1 connecting the first chip pads CP1 and the second chip pads CP2. A second molding member 310 may cover the first substrate 100 and the memory stacked structure 150. The other configurations may be the same/similar to those described with reference to FIGS. 1 to 4C.

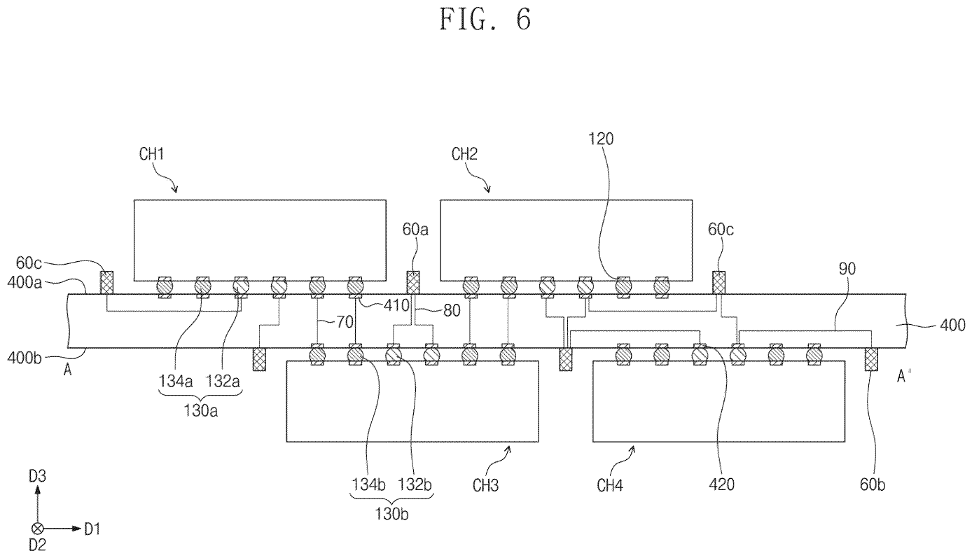

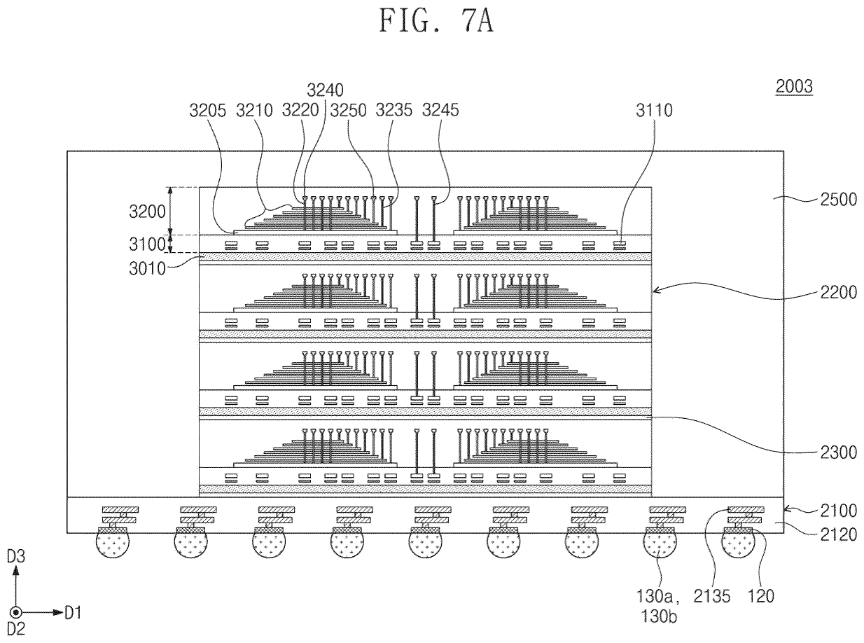

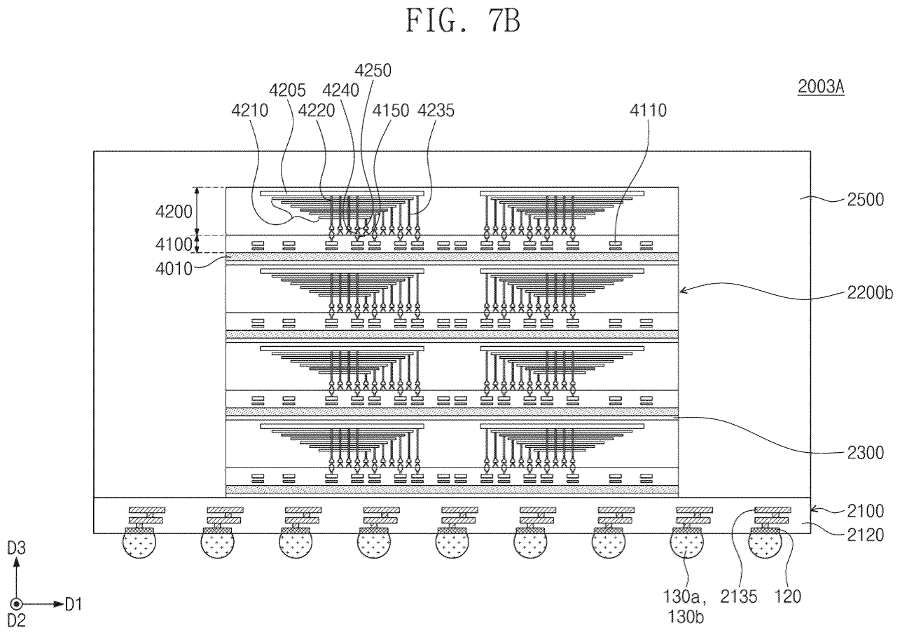

FIG. 6 is a cross-sectional view taken along line A-A′ of FIG. 2 according to one or more embodiments. FIGS. 7A and 7B are cross-sectional views of semiconductor packages according to one or more embodiments.

Referring to FIGS. 6 and 7A, according to one or more embodiments, at least one of first to fourth semiconductor packages CH1, CH2, CH3, and CH4 may be a first sub-semiconductor package 2003 of FIG. 7A. A package substrate 2100 may be a printed circuit board. The package substrate 2100 may include a package substrate body 2120, fourth conductive pads 120 disposed on or exposed through a lower surface of the package substrate body 2120, and internal wiring lines 2135 in the package substrate body 2120. The fourth conductive pads 120 may be connected to the first to third wiring lines 70, 80, and 90 of the module substrate 400 through the first and second connection members 130a and 130b as shown in FIG. 6.

Each of first semiconductor chips 2200 may include a first semiconductor substrate 3010, a first structure 3100, and a second structure 3200 sequentially stacked on the first semiconductor substrate 3010. The first structure 3100 may include a peripheral circuit region including first peripheral wiring lines 3110. The second structure 3200 may include a first source structure 3205, a first stacked structure 3210 on the first source structure 3205, first vertical structures 3220 penetrating the first stacked structure 3210, first bit lines 3240 electrically connected to the first vertical structures 3220, and first cell contact plugs 3235 electrically connected to word lines of the first stacked structure 3210. For example, first bonding structures 3250 may be electrically connected to the first vertical structures 3220 and word lines through first cell contact plugs 3235 that are electrically connected to the first bit lines 3240 and word lines, respectively.

Each of the first semiconductor chips 2200 may include a first penetration wiring line 3245 that is electrically connected to the first peripheral wiring lines 3110 of the first structure 3100 and extends into the second structure 3200. The first penetration wiring line 3245 may be disposed on the outside of the first stacked structure 3210 and may be further disposed to penetrate the first stacked structure 3210. Each of the first semiconductor chips 2200 may further include an input/output pad electrically connected to the first peripheral wiring lines 3110 of the first structure 3100. Adhesive layers 2300 may be disposed on a lower surface of each of the first semiconductor chips 2200. A third molding member 2500 may be disposed on and cover the package substrate 2100 and the first semiconductor chips 2200. The other configurations may be the same/similar to those described with reference to FIGS. 1 to 5.

Referring to FIGS. 6 and 7B, according to one or more embodiments, at least one of the first to fourth semiconductor packages CH1, CH2, CH3, and CH4 may be a second sub-semiconductor package 2003a of FIG. 7B.

Each of second semiconductor chips 2200b may include a second semiconductor substrate 4010, a third structure 4100 on the second semiconductor substrate 4010, and a fourth structure 4200 bonded to the third structure 4100 in a wafer bonding manner on the third structure 4100.

The third structure 4100 may include a peripheral circuit region including a second peripheral wiring line 4110 and second bonding structures 4150. The fourth structure 4200 may include a second source structure 4205, a second stacked structure 4210 between the second source structure 4205 and the third structure 4100, second vertical structures 4220 penetrating the second stacked structure 4210, and third junction structures 4250 electrically connected to word lines of the second vertical structures 4220 and the second stacked structure 4210, respectively.

For example, third bonding structures 4250 may be electrically connected to the second vertical structures 4220 and the word lines through second bit lines 4240 that are electrically connected to the second vertical structures 4220 and second cell contact plugs 4235 that are electrically connected to the word lines, respectively. The second bonding structures 4150 of the third structure 4100 and the third bonding structures 4250 of the fourth structure 4200 may be bonded while making contact with each other. The bonded portions of the second bonding structures 4150 and the third bonding structures 4250 may be formed of, for example, copper (Cu). Each of the second semiconductor chips 2200b may further include an input/output pad electrically connected to second peripheral wiring lines 4110 of the third structure 4100. The other configuration may be the same/similar to that described with reference to FIGS. 1 to 7A.

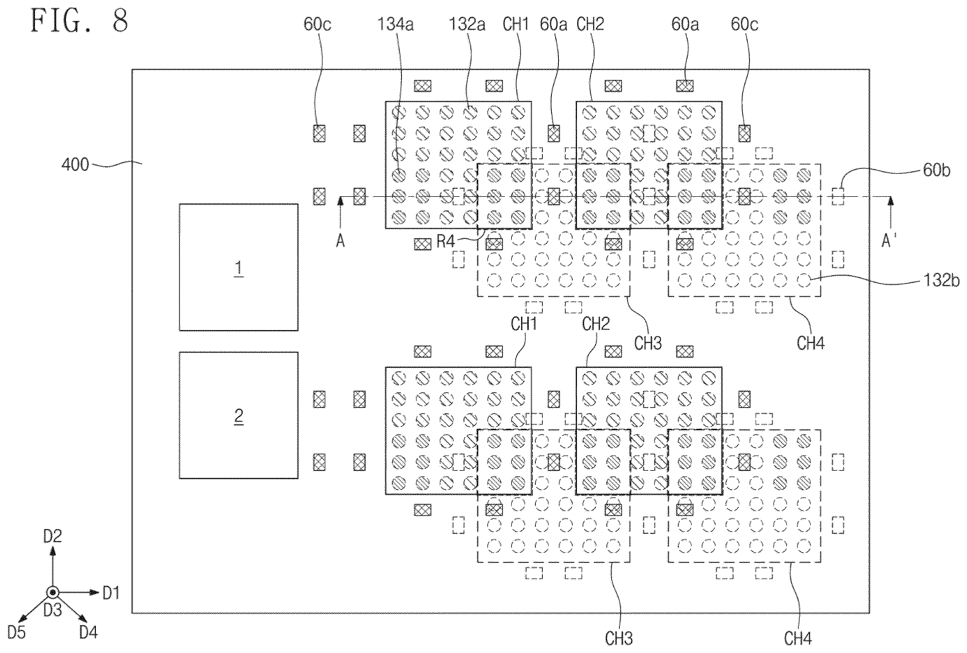

FIG. 8 is a plan view of a semiconductor memory module according to one or more other embodiments.

Referring to FIG. 8, in a semiconductor memory module according to one or more other embodiments, in the structure of FIG. 2, the third semiconductor package CH3 may be misaligned with the first semiconductor package CH1 in a fourth direction D4 and may vertically overlap the first semiconductor package CH1 in the third direction D3 when viewed in a plan view. The fourth direction D4 may be parallel to the first surface 400a of the module substrate 400 and may intersect with the first direction D1 and the second direction D2 simultaneously. The third semiconductor package CH3 may be misaligned with the second semiconductor package CH2 in a fifth direction D5 and may vertically overlap the second semiconductor package CH2 in the third direction D3. The fifth direction D5 may be parallel to the first surface 400a of the module substrate 400 and may simultaneously intersect with the first direction D1, the second direction D2, and the fourth direction D4.

When viewed in a plan view, the fourth semiconductor package CH4 may be misaligned with the second semiconductor package CH2 in the fourth direction D4 and may vertically overlap the second semiconductor package CH2. The first semiconductor package CH1 may have a fourth portion R4 that overlaps the third semiconductor package CH3. The second semiconductor package CH2 may have fourth portions R4 that overlap the third semiconductor package CH3 and the fourth semiconductor package CH4, respectively. The first and second signal connection members 134a and 134b may be disposed in the fourth portions R4. The other configurations may be the same/similar to those described with reference to FIGS. 1 to 7B.

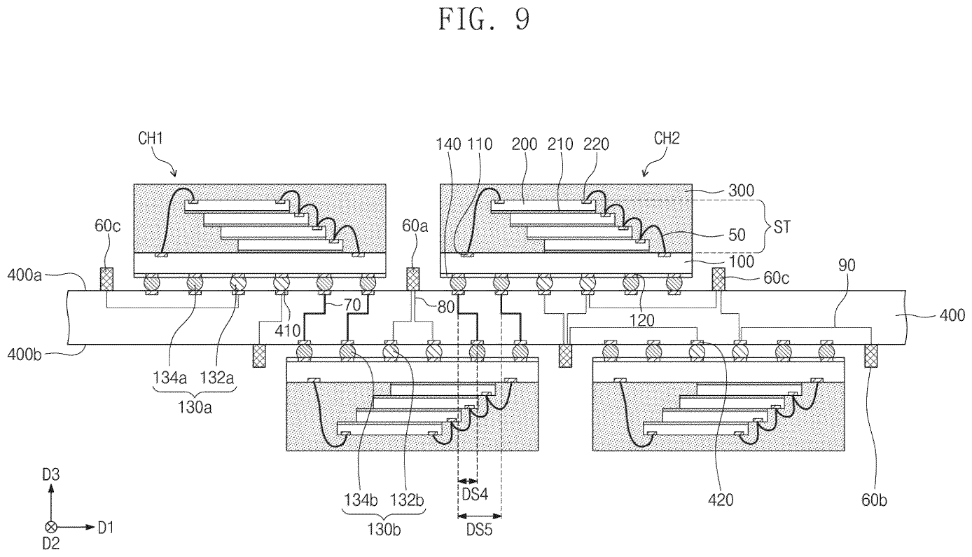

FIG. 9 is a cross-sectional view of a semiconductor memory module according to one or more embodiments.

Referring to FIG. 9, one of the second signal connection members 134b corresponding to one of the first signal connection members 134a may be spaced apart from one of the first signal connection members 134a by a fourth distance DS4 in the first direction D1. The fourth distance DS4 may be less than a fifth distance DS5 between adjacent ones of the first signal connection members 134a. The other configurations may be the same/similar to those described with reference to FIGS. 1 to 8.

At least one of the components, elements, modules or units (collectively “components” in this paragraph) represented by a block in the drawings, may be embodied as various numbers of hardware, software and/or firmware structures that execute respective functions described above, according to an exemplary embodiment. For example, at least one of these components may use a direct circuit structure, such as a memory, a processor, a logic circuit, a look-up table, etc. that may execute the respective functions through controls of one or more microprocessors or other control apparatuses. Also, at least one of these components may be specifically embodied by a module, a program, or a part of code, which contains one or more executable instructions for performing specified logic functions, and executed by one or more microprocessors or other control apparatuses. Further, at least one of these components may include or may be implemented by a processor such as a central processing unit (CPU) that performs the respective functions, a microprocessor, or the like. Two or more of these components may be combined into one single component which performs all operations or functions of the combined two or more components. Also, at least part of functions of at least one of these components may be performed by another of these components. Further, although a bus is not illustrated in the above block diagrams, communication between the components may be performed through the bus. Functional aspects of the above exemplary embodiments may be implemented in algorithms that execute on one or more processors. Furthermore, the components represented by a block or processing steps may employ any number of related art techniques for electronics configuration, signal processing and/or control, data processing and the like.

In the semiconductor memory module according to one or more embodiments, the electrical signal distance between the semiconductor packages may be reduced, and thus the signal transmission speed may be improved and the inductance and resistance may be reduced. In addition, the module substrate and the semiconductor packages may be may electrically connected through the passive elements, and thus the power transmitted from the power circuit chip may be more effectively transmitted to the semiconductor packages. As a result, the semiconductor memory module with the improved electrical characteristics may be provided.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor memory module comprising:
a module substrate comprising a first surface and a second surface that are opposite to each other;
a first semiconductor package and a second semiconductor package on the first surface of the module substrate and side by side in a first direction;
a third semiconductor package on the second surface of the module substrate and partially overlapping the first semiconductor package and the second semiconductor package in a second direction perpendicular to the first direction;
first passive elements on the first surface of the module substrate and between the first semiconductor package and the second semiconductor package; and
second passive elements on the second surface of the module substrate and on a side of the third semiconductor package in the first direction,
wherein at least one of the first passive elements overlaps the third semiconductor package in the second direction.

2. The semiconductor memory module of claim 1, further comprising a fourth semiconductor package on the second surface of the module substrate and partially overlapping the second semiconductor package in the second direction,
wherein a first distance between the first semiconductor package and the second semiconductor package in the first direction is equal to a second distance between the third semiconductor package and the fourth semiconductor package in the first direction.

3. The semiconductor memory module of claim 1, further comprising:
first signal connection members between a peripheral portion of the first semiconductor package and the module substrate, and between a peripheral portion of the second semiconductor package and the module substrate;
first sub-connection members between a central portion of the first semiconductor package and the module substrate, and between a central portion of second semiconductor package and the module substrate;
second signal connection members between a peripheral portion of the third semiconductor package and the module substrate; and
second sub-connection members between a central portion of the third semiconductor package and the module substrate.

4. The semiconductor memory module of claim 3, wherein some of the first signal connection members and the second signal connection members overlapping each other in the second direction are connected to each other.

5. The semiconductor memory module of claim 4, wherein the module substrate has a first thickness in the second direction, and
wherein a third distance between one of the first signal connection members and one of the second signal connection members overlapping each other in the second direction is 0.8 to 1.1 times the first thickness.

6. The semiconductor memory module of claim 3, wherein some of the first sub-connection members are connected to at least one of the second passive elements.

7. The semiconductor memory module of claim 3, wherein some of the second sub-connection members are connected to at least one of the first passive elements.

8. The semiconductor memory module of claim 3, further comprising a third passive element on the first surface of the module substrate and spaced apart from the first passive elements in the first direction, the first semiconductor package being between the third passive element and the first passive elements,
wherein an electrical signal distance between one of the first sub-connection members and the third passive element is greater than an electrical signal distance between the other one of the first sub-connection members and one of the second passive elements.

9. The semiconductor memory module of claim 3, wherein one of the second signal connection members corresponding to one of the first signal connection members is spaced apart from the one first signal connection member by a fourth distance in the first direction, and
wherein the fourth distance is less than a fifth distance between adjacent first signal connection members of the first signal connection members in the first direction.

10. The semiconductor memory module of claim 1, wherein the first semiconductor package has a first width in the first direction,
wherein the third semiconductor package comprises a first portion overlapping the first semiconductor package in the second direction, the first portion having a second width in the first direction,
wherein the second width is 0.3 to 0.5 times the first width,
wherein the second semiconductor package has a third width in the first direction,
wherein the third semiconductor package comprises a second portion overlapping the second semiconductor package in the second direction, the second portion has a fourth width in the first direction, and
wherein the fourth width is 0.3 to 0.5 times the third width.

11. The semiconductor memory module of claim 1, wherein each of the first semiconductor package, the second semiconductor package, and the third semiconductor package comprises a plurality of semiconductor dies which are stacked.

12. The semiconductor memory module of claim 1, further comprising a power circuit chip on the first surface of the module substrate and spaced apart from the first to third semiconductor packages in the first direction.

13. The semiconductor memory module of claim 1, wherein the first passive elements are spaced apart from the second passive elements in the first direction or the second direction.

14. A semiconductor memory module comprising:
a module substrate comprising a first surface and a second surface that are opposite to each other;
a first semiconductor package and a second semiconductor package on the first surface of the module substrate and side by side in a first direction;
first connection members between the first semiconductor package and the module substrate and between the second semiconductor package and the module substrate;
a third semiconductor package on the second surface of the module substrate and partially overlapping the first semiconductor package and the second semiconductor package in a second direction perpendicular to the first direction;
second connection members between the third semiconductor package and the module substrate;
first passive elements on the first surface of the module substrate and between the first semiconductor package and the second semiconductor package; and
second passive elements on the second surface of the module substrate and the third semiconductor package,
wherein the first connection members comprise first signal connection members overlapping a peripheral portion of the first semiconductor package and a peripheral portion the second semiconductor package in the second direction, and first sub-connection members overlapping a central portion of the first semiconductor package and a central portion of the second semiconductor package in the second direction,
wherein the second connection members comprise second signal connection members overlapping, in the second direction, a peripheral portion of the third semiconductor package, and second sub-connection members overlapping, in the second direction, a central portion of the third semiconductor package, and
wherein some of the first signal connection members are connected to and overlap second signal connection members, respectively, in the second direction.

15. The semiconductor memory module of claim 14, wherein some of the first sub-connection members are connected to at least one of the second passive elements, and
wherein some of the second sub-connection members are connected to at least one of the first passive elements.

16. The semiconductor memory module of claim 14, wherein the first semiconductor package has a first width in the first direction,
wherein the third semiconductor package has a first portion overlapping the first semiconductor package in the second direction,
wherein the first portion has a second width in the first direction, and
wherein the second width is 0.3 to 0.5 times the first width.

17. The semiconductor memory module of claim 14 further comprising:
a plurality of first semiconductor packages comprising the first semiconductor package;
a plurality of second semiconductor packages comprising the second semiconductor package;
a plurality of third semiconductor packages comprising the third semiconductor package; and
a power circuit chip on the first surface of the module substrate and spaced apart from the first semiconductor package, the second semiconductor package, and the third semiconductor package in the first direction.

18. A semiconductor memory module comprising:
a module substrate comprising a first surface and a second surface that are opposite to each other;
a first semiconductor package and a second semiconductor package on the first surface of the module substrate and side by side in a first direction;
a third semiconductor package on the second surface of the module substrate and partially overlapping the first semiconductor package and the second semiconductor package in a second direction perpendicular to the first direction;
a fourth semiconductor package on the second surface of the module substrate and partially overlapping the second semiconductor package in the second direction;
first passive elements on the first surface of the module substrate and between the first semiconductor package and the second semiconductor package, and adjacent to a periphery of the first semiconductor package and a periphery of the second semiconductor package; and
second passive elements on the second surface and between the third semiconductor package and the fourth semiconductor package, and adjacent to a periphery of the third semiconductor package and a periphery of the fourth semiconductor package,
wherein a distance between the first semiconductor package and the second semiconductor package in the first direction is equal to a distance between the third semiconductor package and the fourth semiconductor package in the first direction.

19. The semiconductor memory module of claim 18, further comprising:
first signal connection members between a peripheral portion of the first semiconductor package and the module substrate, and between a peripheral portion of the second semiconductor package and the module substrate;
first sub-connection members between a central portion of the first semiconductor package and the module substrate, and between a central portion of the second semiconductor package and the module substrate;
second signal connection members between a peripheral portion of the third semiconductor package and the module substrate, and between a peripheral portion of the fourth semiconductor package and the module substrate; and
second sub-connection members between a central portion of the third semiconductor package and the module substrate, and between a central portion of the fourth semiconductor package and the module substrate.

20. The semiconductor memory module of claim 19, wherein some of the first passive elements are respectively connected to the second sub-connection members, and
wherein some of the second passive elements are respectively connected to the first sub-connection members.
